(19) United States
(12) Patent Application Publication
(10) Pub. No.: US 2010/0156242 A1
(43) Pub. Date: Jun. 24, 2010

(54) Electromechanical actuating drive

(76) Inventors: Heinrich-Jochen Blume, Darmstadt (DE); Bernhard Gottleb, Munchen (DE)

Correspondence Address: STAAS & HALSEY LLP, SUITE 700, 1201 NEW YORK AVENUE, N.W., WASHINGTON, DC, 20005, US

(21) Appl. No.: 12/311,112

(22) PCT Filed: May 31, 2007
(86) PCT No.: PCT/EP2007/055357

§ 371 Date: Nov. 6, 2009

(30) Foreign Application Priority Data
Sep. 19, 2006 (DE) 10 2006 044 000.5

(51) Int. Cl. H01L 41/09

(52) U.S. Cl. 310/331

(57) ABSTRACT

An electromechanical actuating drive, in particular a piezoelectric microstepper motor, has two piezoelectric bending transducers having in each case an effective direction not oriented parallel to one another. Said bending transducers act on a drive ring in order, via the latter, to rotate a shaft. The bending transducers are articulated via a sliding coupling or a shear-flexible structure, thereby minimizing mutual obstruction of the bending transducers during the displacement movement.

### CROSS REFERENCE TO RELATED APPLICATIONS

This application is based on and hereby claims priority to PCT Application No. PCT/EP2007/055357 filed on May 31, 2007 and German Application No. 10 2006 044 000.5 filed on Sep. 19, 2006, the contents of which are hereby incorporated by reference.

### BACKGROUND OF THE INVENTION

The present invention relates to an electromechanical actuating drive, in particular a piezoelectric stepper motor.

The central instrument console of a motor vehicle attempts to realize an optimal interplay between design and technology. Various pointer instruments are situated therein in the driver's field of view. The pointer instruments must not only satisfy different technical requirements but must also be priced competitively in order to be suitable for use in the mass production of motor vehicles. An example of a pointer instrument of said type is the “Messwerk 2000” system from the company Siemens VDO.

The “Messwerk 2000” product is based on a stepper motor drive reduced by a single-stage worm gear. The four-pole stepper motor is controlled as a function of time by two sinusoidal coil current waveforms phase-shifted with respect to each other by a phase angle of 90°. The sign of the phase shift determines the direction of rotation, and the frequency the rotational speed of the motor shaft. Up to 128 intermediate steps can be reproducibly set in the course of one full period of 360° of the sinusoidal current waveforms. The use of these intermediate steps is referred to as microstepping operation.

A complete “Messwerk 2000” actuating drive which includes the above-characterized stepper motor having twelve individual parts. The stepper motor itself is composed of two coils having a common stator plate and a permanent magnet rotor. In terms of component costs, the coils and the permanent magnet are the most expensive items. Also critical for the price in addition to the material costs are the manufacturing costs, which increase approximately proportionally to the number of components making up the actuating drive. These high material costs as well as the increase in manufacturing overhead for the actuating drive as the number of individual parts grows have a disadvantageous impact in terms of its mass production.

### SUMMARY

The inventors considered the technical problem of providing a small-format actuating drive that is suitable for mass production and can be used for example for measurement elements of central console instruments in the motor vehicle.

The inventors propose an electromechanical actuating drive having the following features: at least two electromechanical, preferably piezoelectric, drive elements, each of which has an effective direction oriented non-parallel to the other, a shaft rotatably mounted in a drive ring such that by a deflection of the piezoelectric drive elements in the effective direction the drive ring can be stimulated into a displacement movement which can be transmitted directly onto the shaft, with the result that the shaft rolls in contact with the drive ring and thereby rotates, while the at least two electromechanical drive elements are linked via a slip coupling or a shear-flexible structure such that a mutual obstruction of the drive elements during the displacement movement is minimized.

The electromechanical actuating drive or rotatory actuating drive is operated with the aid of solid-state actuators, in particular strip-shaped solid-state bending actuators, as electromechanical energy converter elements. Bending actuators of this type based on piezoelectric ceramic material, which are referred to in the present context as electromechanical drive elements, have been used in different designs in multifarious applications in industry for many years. They are characterized by a small design format, low energy requirements and high reliability. Thus, for example, a piezoelectric bending actuator exhibits a service life of at least 10⁹ cycles in the industrial environment.

The at least two electromechanical, preferably piezoelectric, drive elements are arranged in such a way that their directions of movement are decoupled from each other, with the result that the drive elements do not obstruct each other in their movement or impede each other only to a negligibly small degree. For that purpose the drive elements are secured at least at one end with the aid of a sliding gate or a shear-soft, pressure- and tension-stable flexible structure. The sliding gate or, as the case may be, shear-soft, pressure- and tension-stable flexible structure allows free or approximately free movement of the drive elements in their longitudinal direction relative to the drive ring, while in another direction, preferably perpendicular to the longitudinal axis of the drive element, they are rigidly or immovably fixed. In this way the electrical energy converted into motion by the drive elements is optimally transferred onto the drive ring without energy losses occurring due to the mutual obstruction of the drive elements.

According to one embodiment, the piezoelectric drive elements of the actuating drive are bending transducers having in each case a longitudinal direction and being oriented at right angles, parallel or arbitrarily to each other, such that a space requirement of the actuating drive can be optimally matched to given spatial conditions. In other words, the two piezoelectric drive elements are arranged in such a way that the two electromechanical drive elements lie in a plane spanned by the effective directions and in two different tangential planes referred to an inner opening of the drive ring having a center point such that in the case of a rotationally symmetrical arrangement of the drive elements about the center point the two different tangential planes are arranged offset relative to each other by an angle γ in the range of 180°<γ<360°, preferably γ=270°, or in the case of a rotationally symmetrical arrangement of the drive elements at an imaginary diameter of the drive ring the two different tangential planes are arranged offset relative to each other by an angle γ in the range of 0°<γ<180°, preferably γ=90°, or the two piezoelectric drive elements lie outside the plane spanned by the effective directions and in two different tangential planes referred to the inner opening of the drive ring, or one of the two piezoelectric drive elements lies in the plane spanned by the effective directions and the other drive element lies outside the plane spanned by the effective directions and they lie in two different tangential planes referred to the inner opening of the drive ring.

The piezoelectric bending transducers have the following advantages: They are available in a wide variety of designs and packaged in a small volume. In addition they are characterized by high dynamic performance, low energy requirements and high reliability. A further advantage is that they are also equipped with inherent sensor properties. In a preferred embodiment, the essentially strip-shaped bending transducers are mechanically rigidly clamped or secured at one end. The electrical contacting of the bending transducers is also preferably implemented at the end. According to the electrical stimulation of the bending transducer, a deflection into its effective direction is achieved at the opposite, moving end. The bending transducers employed in a small-format actuating drive for e.g. pointer instruments are typically dimensioned such that they exhibit a free deflection in the range of approx. 0.2 mm to 2 mm at their moving end. Furthermore, if the deflection of the freely movable end of the bending transducer is blocked, a blocking force in the range of 0.5 N to 2 N is achieved. The approximately rectilinear deflection of the bending transducers takes place in each case transversally referred to their greatest longitudinal extension. The direction of the deflection corresponding to the effective direction of the bending transducer is thus approximately orthogonal to the longitudinal axis of the bending transducer. Preferably at least two mutually independently deflectable bending transducers having effective directions that are non-parallel, but preferably disposed orthogonally to one another are required inside the actuating drive in order to displace the drive ring coupled to the moving ends of the two bending transducers by overlaying the individual movements of the bending transducers into any arbitrary even movement. With this construction the movement plane or effective plane is spanned by the effective directions of the bending transducers. Since the effective direction of the bending transducer is oriented approximately at right angles to its longitudinal axis, it is advantageous to arrange the longitudinal directions of the bending transducers parallel to each other, at right angles to each other or in another angular orientation. In this way the actuating drive can be adapted to local conditions and spatial constraints without the transmission of the movement into the drive ring being adversely affected.

In addition to the securing of the drive elements already described above it is preferred to fix them at one end securely to the drive ring or on a housing, while the other end acts correspondingly on the housing or the drive ring via the slip coupling or the shear-flexible structure. In a further embodiment of the connection between drive element and drive ring, the drive ring has projections for picking up the deflection of the respective drive element, while the projection and the drive element acting in each case are aligned in relation to the effective direction of a further drive element in such a way that a sliding of the projection on the acting drive element is ensured.

The aforementioned decoupling of the at least two drive elements is realized with the aid of this construction. In addition thereto, a guiding of the drive ring on the respective drive element is likewise provided, such that the movements of the drive elements transmitted onto the drive ring are transferred in a controllable and loss-free manner.

According to a further embodiment, the electromechanical actuating drive includes two electromechanical drive elements, each of which has a longitudinal axis and an effective direction oriented non-parallel to the other, a shaft arranged in a drive ring in such a way that by a deflection of the electromechanical drive elements in the effective direction the drive ring can be stimulated into a displacement movement which can be transmitted directly onto the shaft, while the two electromechanical drive elements are fixedly connected at their ends to the drive ring and a housing, and the two electromechanical drive elements are arranged in such a way that the two electromechanical drive elements lie in a plane spanned by the effective directions and in two different tangential planes referred to an inner opening of the drive ring having a center point such that in the case of a rotationally symmetrical arrangement of the drive elements about the center point the two different tangential planes are arranged offset relative to each other by an angle γ in the range of 180°<γ<360°, preferably γ=270°, or in the case of a mirror-symmetrical arrangement of the drive elements at an imaginary diameter of the drive ring the two different tangential planes are arranged offset relative to each other by an angle γ in the range of 0°<γ<180°, preferably γ=90°, or the two electromechanical drive elements lie outside the plane spanned by the effective directions and in two different tangential planes referred to the inner opening of the drive ring, or one of the two electromechanical drive elements lies in the plane spanned by the effective directions and the other drive element lies outside the plane spanned by the effective directions and they lie in two different tangential planes referred to the inner opening of the drive ring.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 A, B, C, C′ show three different embodiments of the actuating drive,

FIG. 2 A, B, C, C′ show three further embodiments of the actuating drive,

FIG. 3 A, B, C, C′ show three further preferred embodiments of the actuating drive,

FIG. 4 A, B, C, C′ show three further embodiments of the actuating drive,

FIG. 5 A, B, C, C′ show three further embodiments of the actuating drive,

FIG. 6 A, B, C, C′ show three further embodiments of the actuating drive,

FIG. 7 A, A′ show a further embodiment of the actuating drive with shear-flexible structure,

FIG. 8 shows an embodiment of the actuating drive with housing, and

FIGS. 9 to 15 show different embodiments of the shear-flexible structure of the actuating drive.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

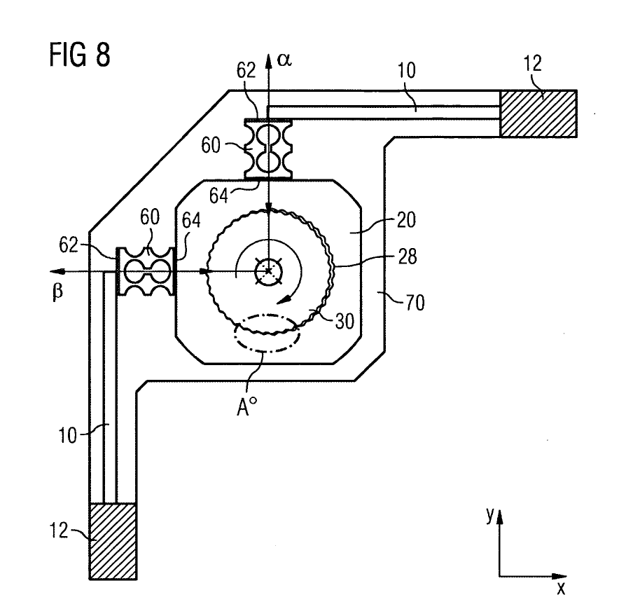

A piezoelectric stepper motor 1 is presented which permits a continuous and uniform rotation to be generated by an overlaying of suitable periodic linear movements of the bending transducers 10. For that purpose the bending transducers 10 are coupled to a flat drive ring 20 in such a way that the latter can be translated in an effective plane along the effective directions α, β of the bending transducers 10. The bending transducers 10 are preferably arranged such that their effective lines or, as the case may be, effective directions α, β intersect at an angle of approximately 90°. The drive ring 20 contains a cylindrical bore 28 having a specific diameter. The bore axis runs ideally vertically with respect to the effective plane which is spanned by the effective directions α and β of the bending transducers 10. Furthermore, the bore axis preferably runs through the point of intersection X of the effective lines α, β of the bending transducers 10 (cf. FIG. 8). This enables the drive ring 20 to be translated in any desired manner in the effective plane in the region of the deflections of the bending transducers 10. The cylindrical ring bore 28 having a specific inner diameter comprises a cylindrical shaft 30 with a slightly smaller outer diameter than the inner diameter of the drive ring 20. The shaft 30 is preferably rotatably, but not displaceably, mounted in a housing 70 (cf. FIG. 8) parallel to the axis of the ring bore 28 and around its own cylinder axis. By a suitable electrical stimulation of the two bending transducers 10 the drive ring 20 can be translated on a circular path in such a way that the outer wall of the shaft 3 rolls in contact with the cylindrical inner surface of the ring bore 28 of the drive ring 20 and is thereby set into rotation. As a necessary prerequisite the deflection range of the bending transducers 10 must exceed the difference in diameter between the ring bore of the drive ring 20 and the outer diameter of the shaft 30 so that the inner wall of the drive ring 20 and the shaft 30 always remain in contact.

The piezoelectric bending transducers 10 are approximately purely capacitive electrical components which are characterized by their electrical capacitance. Their electrical control variables charge and voltage are therefore interlinked and strictly speaking only two control variants exist. In the case of voltage control an operating voltage or a time-related voltage characteristic is impressed and the accepted charge establishes itself. In the case of charge control the amount of charge is impressed and the voltage establishes itself. The control signal can therefore be a predefined voltage or charge function. Since the deflection characteristic of the piezoelectric bending transducers 10 is in a good approximation directly proportional to the control signal, the circular translation of the drive ring 20 can be generated by a charge- or voltage-controlled activation of the bending transducers 10 by two control functions phase-shifted relative to each other by a 90° phase angle and having a sinusoidal time characteristic. The direction of rotation can be defined via the sign of the phase shift, while the rotational speed is determined by the frequency of the control function.

A quasi-static mode of operation can be realized with the aid of the above-described construction of the actuating drive 1. Since the shaft 30 rolls in contact with the inner surface of the drive ring 20, this leads on the one hand to a slight wearing of the shaft 30 and drive ring 20. On the other hand a uniform rotary movement of the shaft 30 is generated on the basis of the activation. A further advantage is that a high reduction ratio can be achieved for the rotary movement without the use of an external gearing mechanism. This reduces the number of components compared with known solutions from the related art. If the inner diameter of the drive ring 20 is designated by D and the outer diameter of the shaft 30 by d, a reducing factor is yielded in accordance with the formula (D−d)/d. The reduction ratio forms the basis for a good angular resolution of the rotary movement of the shaft 30.

In the simplest case the transmission of energy from the drive ring 20 onto the shaft 30 is achieved by friction. In this case slippage is caused as a function of the load torque of an actuating drive 1 constructed in this way acting on the shaft 30, as a result of which the precision of the actuating drive 1 is reduced. The slippage is preferably reduced by installing a gear teeth system on the inner surface of the drive ring 20 and on the outer surface of the shaft 30. In this case the drive ring 20 and shaft 30 preferably have a tooth difference of at least one. This means that the gear teeth system of the inner surface of the drive ring 20 comprises at least one tooth more than the outer surface of the shaft 30. If drive ring 20 and shaft 30 are operated inside the actuating drive 1 in such a way that the gear teeth do not become disengaged, the actuating drive 1 will ideally operate free of slippage.

A cycloidal gearing of drive ring 20 and shaft 30 is considered particularly preferred. With cycloidal gearing, virtually half of all the teeth are in engagement, thereby enabling a high torque to be transmitted between drive ring 20 and shaft 30. Initially a reduction ratio of the actuating drive 1 typically lying in a range of 20:1 to 200:1 is defined via the number of teeth contained on the inner surface of the drive ring 20 and the outer surface of the shaft 30. In order to advance the actuating drive 1 by just one tooth, which is to say to rotate the shaft 30 by one tooth further by the drive ring 20, a full period of the controlling sinusoidal signal of the actuating drive 1 must preferably be completed. Since one cycle of the control signal must be completed in order to advance by one tooth, the actuating drive 1 is characterized by high precision and by high repeatability. Furthermore, a high angular resolution of the actuating drive 1 is realized by way of the number of teeth and the use of one cycle of the control signal per tooth. In addition thereto it is possible to interpolate arbitrarily within a period of the control signal in order to ensure a microstepping operation of the actuating drive 1. According to preferred structural designs the actuating drive 1 thus delivers high efficiency, a high reduction ratio, a high transmissible torque based on the gear teeth engagement of drive ring 20 and shaft 30, freedom from slippage in the transmission of the torque, arbitrary interpolation of the rotation angle within a tooth of the shaft 30 (microstepping operation), small drive torque variations (ripple) and a low tooth flank loading for drive ring 20 and shaft 30, thereby likewise reducing wear.

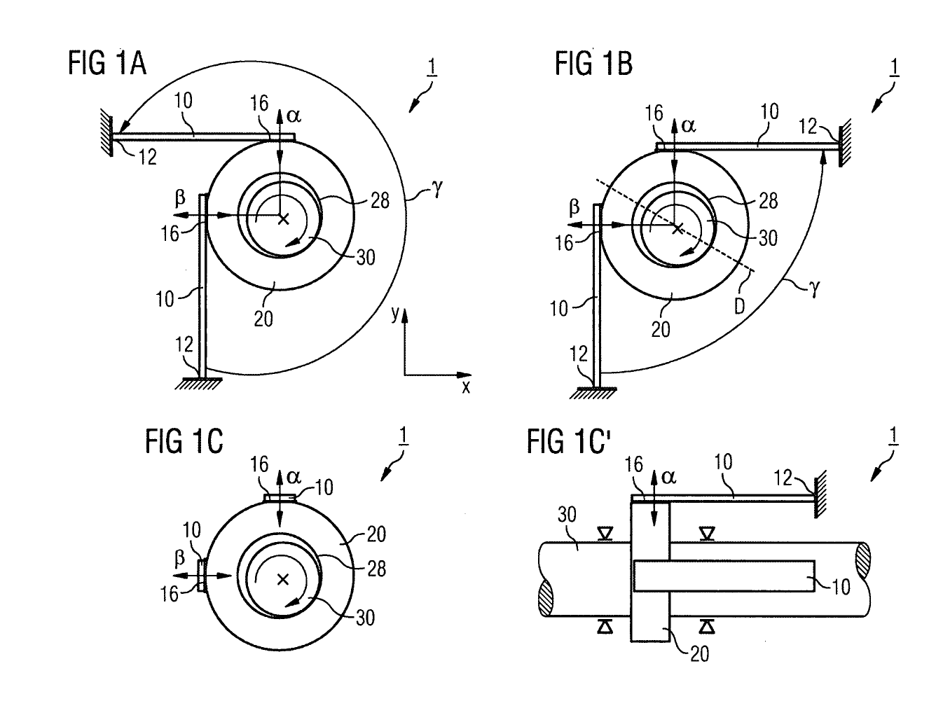

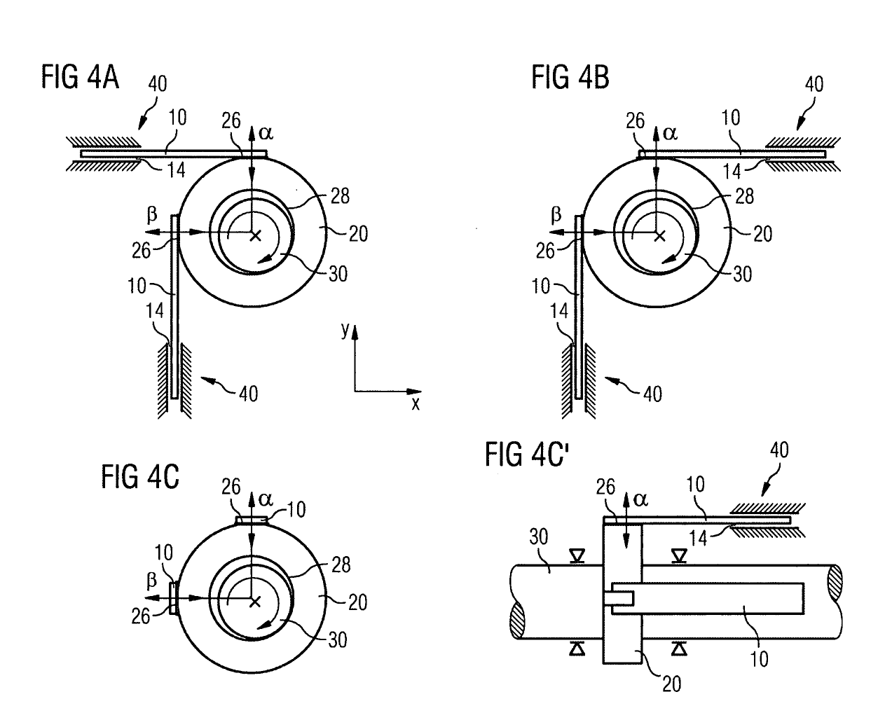

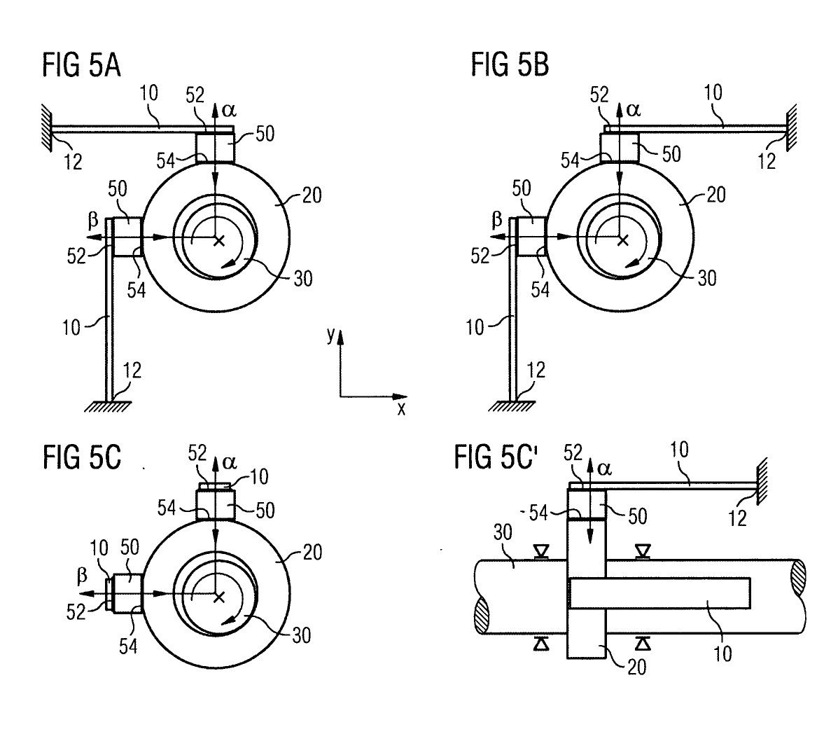

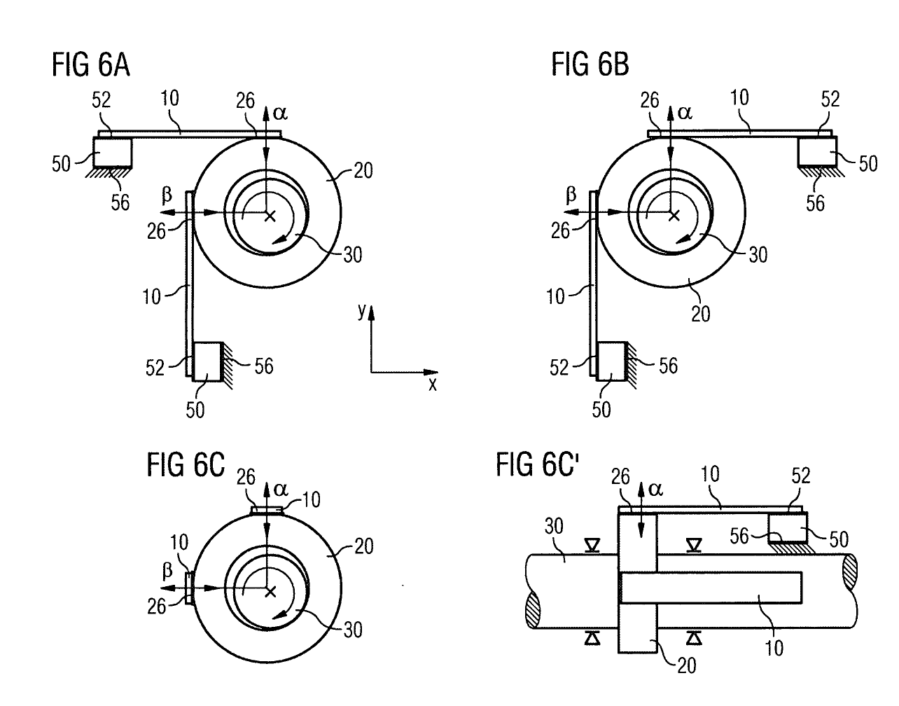

Strip-shaped piezoelectric bending transducers 10 that satisfy the aforementioned requirements behave mechanically “softer” in their effective direction α, β than in any other spatial direction. This property should be taken into account when coupling the bending transducers 10 to the drive ring 20. If the bending transducers 10 are mounted mechanically rigidly in a stationary housing 70 (cf. FIG. 8) at their clamping end 12 and are also coupled mechanically rigidly to the movable drive ring 20 at their moving end, then one bending transducer 10 operates in its effective direction a in each case against the comparatively high mechanical rigidity of the other bending transducer 10. This structure is already operative to a limited extent. In order to decouple the movements of the bending transducers 10 acting on the drive ring 20 in a suitable manner, the movements of the bending transducer 10 are transmitted onto the drive ring 20 in each case via a slip coupling 40 (cf. FIGS. 1 to 3) or a shear-flexible structure 50, 60 (cf. FIGS. 5 to 8). The decoupling of the movements of the bending transducers 10 is characterized in that the drive ring 20 is mechanically rigidly coupled to each of the bending transducers 10 in relation to its respective effective direction α, β. Furthermore the bending transducers 10 do not mutually obstruct each other in their effective direction α, β, which is to say that they behave mechanically softly in the effective direction α, β of the other bending transducer 10 in each case. This is preferably achieved by a sliding of the bending transducer 10 on the drive ring 20 perpendicularly to its effective direction α, β or by a low shear rigidity of the shear-flexible structure 50, 60 perpendicularly to its effective direction α, β. The decoupling is also characterized in that it behaves in a torsionally rigid manner in relation to the load torques transmitted from the shaft 30 onto the drive ring 20. The decoupling is achieved in that the slip coupling 40 or the shear-flexible structure 50, 60 is disposed between the drive ring 20 and the movable end of the bending transducer 10. A further alternative positions the shear-flexible structure 50, 60 and the slip coupling 40 between the bending transducer 10 and the housing 70 (cf. FIGS. 4, 6). In this case the movable end of the bending transducer 10 would be fixedly secured to the drive ring 20. These different embodiments are explained in more detail below with reference to FIGS. 1 to 8.

Noteworthy as further advantages of the shear-flexible structure 50, 60 and the slip coupling 40 in addition to the decoupling is that they increase the efficiency of the translation of the linear movement of the bending transducers 10 into a rotation of the shaft 30. They also improve the linearity of the conversion of the phase of the control function into an angle of rotation of the actuating drive 1.

Various embodiments are shown in the accompanying drawings. Similar components of the electromechanical actuating drive 1 are identified by the same reference signs in each of the different embodiments. FIGS. 1 A, B, C, C′ show first embodiments. FIG. 1 A shows a schematic sectional view of the electromechanical actuating drive 1. The actuating drive 1 comprises at least two drive elements 10. The drive elements 10 are mechanically rigidly fixed to a housing (not shown) at point 12. Furthermore, the drive elements 10 are mechanically rigidly fixed to a drive ring 20 at point 16. The mechanically rigid fixing or connection between drive element 10 and drive ring 20 as well as housing is realized by an adhesive bond or a plug-in connection. It is also preferred to secure the drive elements 10 in suitable mounts on the housing.

According to one embodiment the drive elements 10 are formed by piezoelectric bending transducers. The bending transducers 10 each have an effective direction α, β in which they deflect when suitable electrical stimulation is applied. The deflection can take place in both arrow directions of the arrows α, β in FIG. 1 A.

The deflection is transmitted onto the drive ring 20 in order to drive a shaft 30. The shaft 30 is disposed inside an opening 28 of the drive ring 20 and runs vertically with respect to the effective direction α, β of the bending transducers 10. The bending transducers 10 are preferably disposed in such a way that the effective directions α and β converge at right angles in space and form an imaginary point of intersection X in the center of the drive ring 20. Owing to the arrangement of the bending transducers 10 the effective directions α, β span an effective plane which lies in the sheet plane of FIG. 1 A. According to the embodiments shown in FIGS. 1 A and B, the bending transducers 10 are arranged within this effective plane. Referred to the opening 28 in the drive ring 20, the bending transducers 10 lie in different tangential planes. The tangential planes run vertically with respect to the sheet plane of FIGS. 1 A and B parallel to an imaginary tangent to the inner opening 28 of the drive ring 20.

In the embodiments shown, the tangential planes of the bending transducers 10 are preferably oriented at right angles to one another, while other angular orientations relative to one another not equal to 0° are also conceivable here. According to the embodiment shown in FIG. 1 A, the bending transducers 10 are arranged in the tangential planes rotationally symmetrically about the center point X of the drive ring 20. The tangential planes are arranged offset relative to one another by an angle of γ=270° measured in the counterclockwise direction. It is also possible to arrange the bending transducers 10 rotationally symmetrically in tangential planes which are arranged offset relative to one another by an arbitrary angle γ in the range of 180°<γ<360°.

In the embodiment according to FIG. 1 B, the bending transducers 10 are arranged in the tangential planes mirror-symmetrically to an imaginary diameter D of the drive ring 20. The tangential planes in the mirror-symmetrical arrangement of the drive elements 10 are preferably offset relative to one another by an angle of γ=90°. It is also preferred to arrange the bending transducers 10 in tangential planes which are arranged offset relative to one another at an arbitrary angle γ in the range of 0<γ<180°.

FIGS. 1 C and C′ show a further embodiment of the actuating drive 1 in a plan view and in a side view. In this case the bending transducers 10 are likewise arranged in tangential planes offset at an angle relative to one another. According to the embodiment shown, the bending transducers 10 are also arranged outside the effective plane spanned by the effective directions α, β and preferably both run parallel to each other and to the shaft 30. It is also preferred to arrange the bending transducers 10 non-parallel to each other and at an arbitrary angle in relation to the shaft 30 within the respective tangential plane. According to a further embodiment (not shown) of the actuating drive 1, only one of the bending transducers 10 is arranged within the effective plane, while both bending transducers 10 are arranged in different tangential planes.

Despite the above-described different spatial arrangements of the bending transducers 10 inside the actuating drive 1, the effective direction α, β of the respective bending transducer 10 is oriented in the radial direction of the drive ring 20. This orientation enables an optimal transmission of force or an optimal displacement of the drive ring 20 by the deflection of the respective bending transducer 10. In addition to the optimal control of the drive ring 20 by way of the deflection of the bending transducers 10, the actuating drive 1 can be optimally adapted to spatial conditions and constraints by the different spatial alignment of the bending transducers 10.

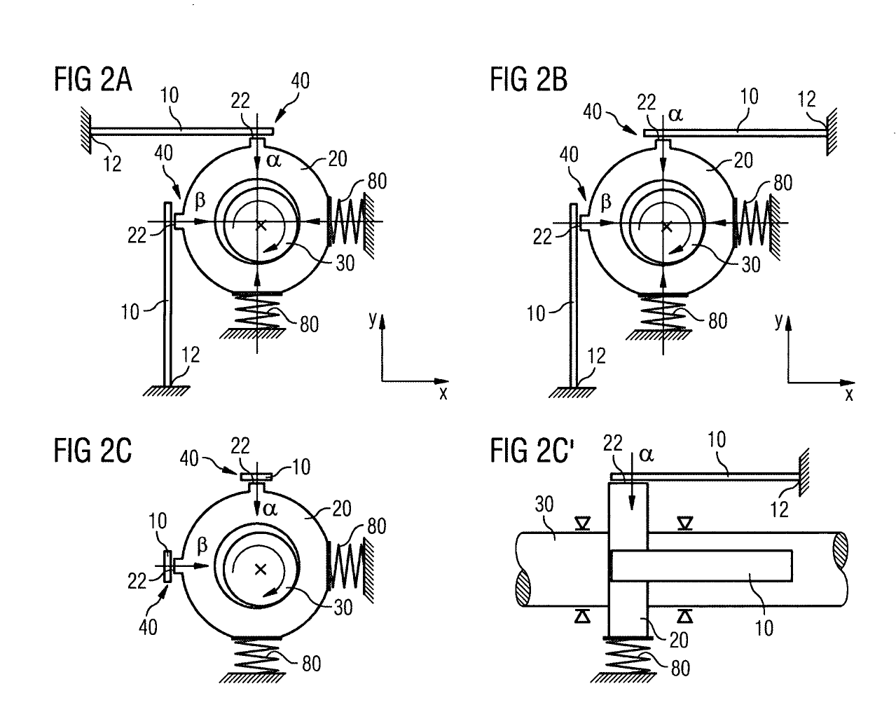

The spatial arrangement possibilities of the bending transducers 10 in the actuating drive 1 described with reference to the embodiments shown in FIG. 1 are equally applicable to the embodiments of the actuating drive shown in FIGS. 2, 3, 4, 5, 6, 7 and 8, without the arrangements being repeated once again for these embodiments.

In the embodiments shown in FIGS. 2 A, B, C, C′, the bending transducers 10 are linked to the drive ring 20 by way of a slip coupling 40. The slip coupling 40 enables the movements of the two bending transducers 10 to be decoupled from each other. In this way one bending transducer 10 does not restrict the movement of the other bending transducer 10 in each case, because the drive ring 20 can move along the longitudinal axis of the bending transducer 10 and is not rigidly fixed.

According to one embodiment, the slip coupling 40 includes a projection 22 on the drive ring 20 at which projection 22 the corresponding end of the bending transducer 10 is subject to pressure. The pressure of the bending transducer 10 on the projection 22 is preferably generated by way of a spring-loaded element 80. Seen in the effective direction α, β in each case, the spring-loaded element 80 is arranged opposite the end of the bending transducer 10 acting on the drive ring 20. The spring-loaded elements 80 ensure the bending transducers 10 are in contact with the projection 22 or generally with the drive ring 20 even without the bending transducer 10 being fixed to the drive ring 20. The spring-loaded elements 80 are coupled to the drive ring 20 on the outer surface of the ring. The spring-loaded elements 80 are supported on the side facing away from the ring against the housing 70 which is not shown in further detail.

It is also conceivable to provide the drive ring without the projections 22 and in this way allow the bending transducers 20 to act directly on the drive ring 20. In order to reduce the friction between projection 22/drive ring 20 and bending transducers 10, the projection 22/drive ring 20 has a smooth tangentially ground outer surface. With reference to the spatial orientation of the bending transducers 10 in the actuating drive 1, the same possibilities exist as have been explained in connection with the embodiments shown in FIG. 1.

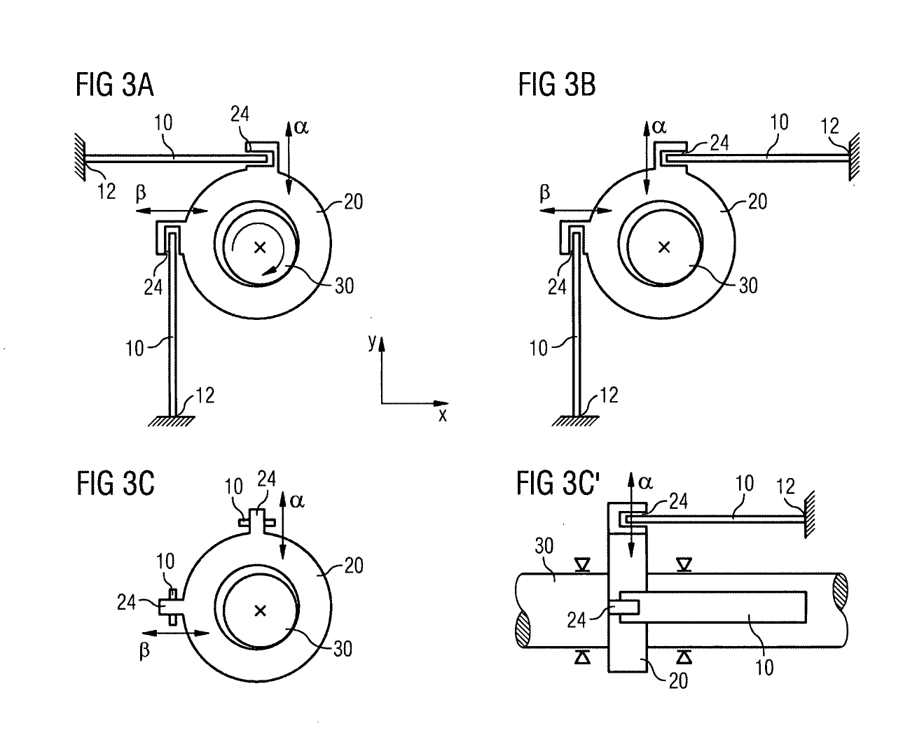

FIGS. 3 A, B, C, C′ likewise show embodiments of the actuating drive 1 in which the bending transducers 10 are coupled mechanically rigidly to the drive ring 20 under pressure and tension. The other side of the bending transducer 10 in each case is mechanically rigidly and fixedly arranged in mounts 12 of the housing (not shown). For this pressure-tension coupling of the bending transducers 10 to the drive ring 20, instead of the projection 22 shown in FIG. 2 the drive ring 20 in each case has U-shaped projections 24 at the corresponding contact points of the bending transducers 10. The U-shaped projection 24 encloses the movable end of the bending transducer 10 in such a way that movements of the bending transducer 10 can be transmitted onto the drive ring 20 in both arrow directions of the effective directions α, β. According to FIG. 3, the U-shaped projection 24 is implemented in such a way that sufficient play is present in each case in the longitudinal direction of the drive elements 10. According to a further embodiment, the U-shaped projection 24 is therefore arranged in such a way that it encloses the bending transducer 10 from the side, such that seen in each case in the longitudinal direction of the bending transducer 10, the U-shaped projection 24 is open or displaceable in the longitudinal direction of the bending transducer 10 without being blocked by the projection 24 itself.

It is also preferred to embody the projection 24 as bridge-shaped so that the movable end of the bending transducer 10 can be inserted into the bridge shape. The movements of the bending transducers 10 would also be decoupled from one another, because the bridge-shaped projection is open in the longitudinal direction of the bending transducers 10 and therefore the drive ring 20 would be displaceable parallel to the longitudinal direction of the bending transducer 10.

In FIGS. 3 C, C′, the U-shaped projection 24 encloses the movable end of the bending transducer 10 in such a way that seen in the longitudinal direction of the bending transducer 10 the U-shaped projection 24 is closed. A pressure-tension coupling of the bending transducer 10 to the drive ring 20 and a decoupling of the movements of the bending transducers 10 from one another are likewise realized by this arrangement.

In the embodiments shown in FIG. 4, two bending transducers 10 are mechanically rigidly coupled to the drive ring 20 of the actuating drive 1 tangentially to the circumferential outer surface of the drive ring 20 and hence also tangentially to its opening 28 on one side 26 in each case. The couplings 26 are preferably implemented by adhesive bonding or plug-in connections. The other side of the bending transducer 10 in each case is secured in a slip coupling 40. In the embodiments shown in FIGS. 4 A, B, the slip coupling 40 ensures that the bending transducers 10 can be displaced in their respective longitudinal direction, but in all other spatial directions are fixedly mounted in mounts of the housing which is not shown in further detail. The embodiments in FIGS. 4 C, C′ show a further configuration of the slip coupling 40. In this case the bending transducers 10 are arranged inside the slip coupling 40 transversely displaceable with respect to their longitudinal direction, while in all other spatial directions they are arranged fixedly. The decoupling of the movements of the bending transducers 10 is also achieved in this way, with the result that they do not mutually obstruct one another. In keeping with the embodiments of FIGS. 1 to 3 already discussed above, the bending transducers 10 are preferably arranged such that the effective directions α and β converge at right angles to each other in space and intersect in the imaginary center of the drive ring 20.

In the embodiments shown in FIGS. 5 A, B, C, C′, the two bending transducers 10 are fixed to the drive ring 20 via a shear-flexible structure 50. The shear-flexible structure 50 is characterized in that it establishes a mechanically rigid or pressure-stable connection to the drive ring 20 in the effective direction α, β of the bending transducers 10. The shear-flexible structure 50 is soft or flexible vertically with respect to the effective direction α, β.

Owing to these characteristics of the shear-flexible structure 50, in the case of a movement of the bending transducer 10 in the effective direction α, the shear-flexible structure 50 allows a movement of the drive ring vertically with respect to the effective direction β at the second bending transducer 10. In this way the movements of the two bending transducers 10 are decoupled.

The shear-flexible structure 50 is fixed to the bending transducer 10 and to the drive ring 20 via the boundary surfaces or fixings 52, 54. At their end 12 facing away from the drive ring 20 the bending transducers 10 are in turn fixedly mounted in mounts of the housing (not shown). Here too, different spatial arrangements of the bending transducers 10 are possible once again in order to match the space requirements of the actuating drive 1 to the spatial conditions in an optimal manner (cf. description relating to FIG. 1).

As already shown in the embodiments of FIGS. 3 and 4, for the purpose of decoupling the movements of the bending transducers 10 the slip coupling 40 is preferably arranged both between bending transducer 10 and drive ring 20 and between bending transducer 10 and the housing (not shown) or the otherwise fixed linkage of the bending transducer 10. According to the embodiments shown in FIGS. 6 A, B, C, C′, it is therefore also preferred to arrange the shear-flexible structure 50 between bending transducer 10 and the housing (not shown) of the actuating drive 1. The shear-flexible structure 50 is fixed to the housing (not shown) of the actuating drive 1 via the boundary surface 56 for example. The boundary surface 52 establishes the connection between the shear-flexible structure 50 and the bending transducer 10. The connections 52, 56 can be established inter alia by adhesive bonding, clamping, plugging-in or similar. The other movable end of the bending transducer 10 in each case is fixedly linked to the drive ring 20.

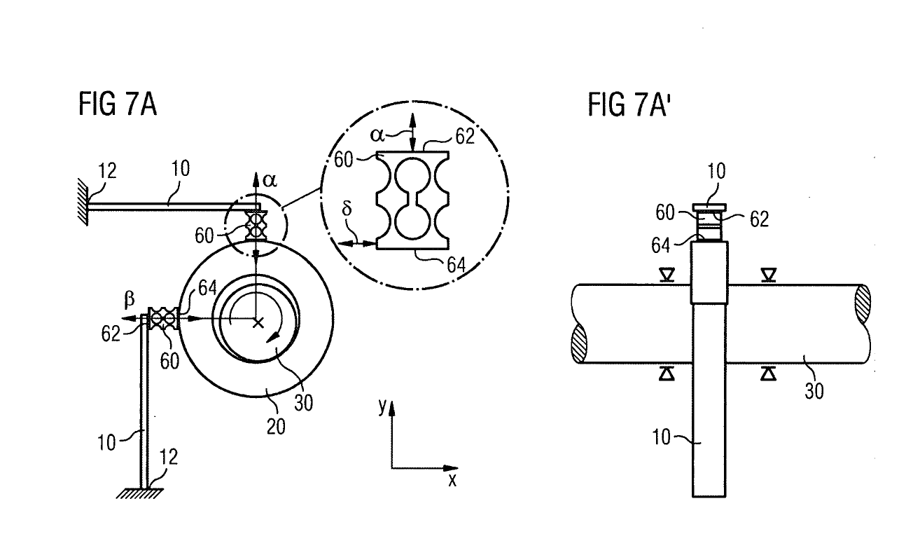

A further embodiment of a shear-flexible structure 60 inside the actuating drive 1 is shown in FIG. 7. The embodiment according to FIG. 7 is essentially equivalent to the embodiment according to FIG. 5. However, in FIGS. 5 and 6 the shear-flexible structure 50 is represented generally as a block having special mechanical properties. The special feature of the block 50 is a mechanically high rigidity in the effective direction α, β of the bending transducer 10 coupled thereto and a mechanically soft behavior, at least in an effective direction arranged vertically thereto, of further bending transducers 10 coupled to the drive ring 20. The layout of the shear-flexible structure 60 in terms of its design is shown in more detail in FIG. 7. The shear-flexible structure 60 is connected to the drive ring 20 and the bending transducer 10 via the boundary surfaces 62, 64. As can be seen in the detail enlargement of FIG. 7, the shear-flexible structure 60 has a specific construction with tapers and thicker parts which generate pressure and tension stability and rigidity parallel to the effective direction a of the bending transducer 10 coupled thereto. Furthermore the shear-flexible structure 60 ensures a flexibility in the arrow directions δ in order to decouple the movements of the two bending transducers 10 of the actuating drive 1.

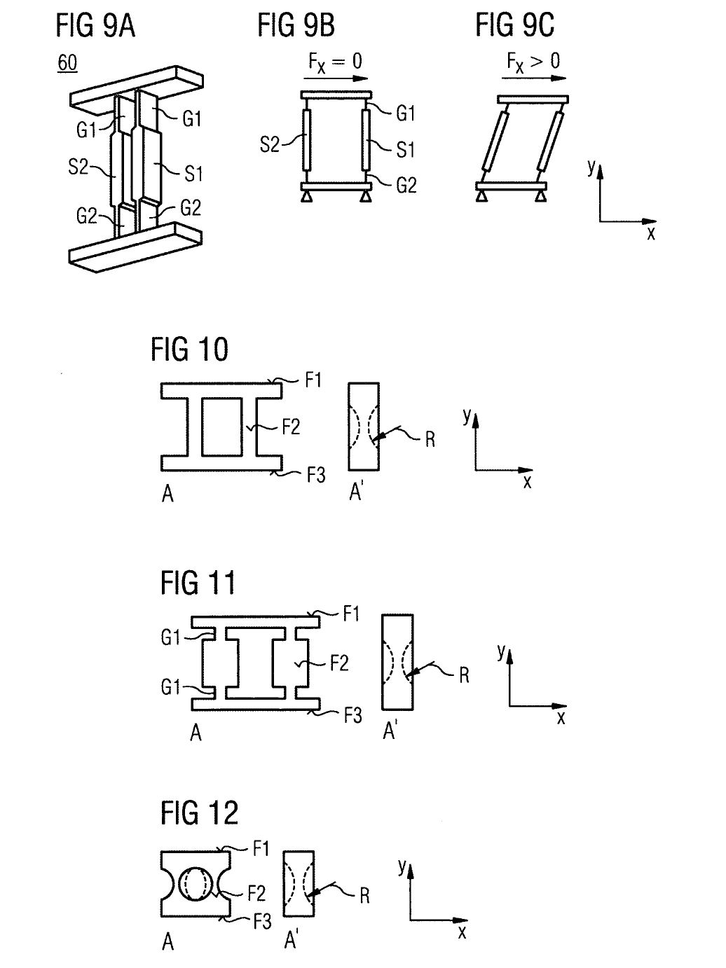

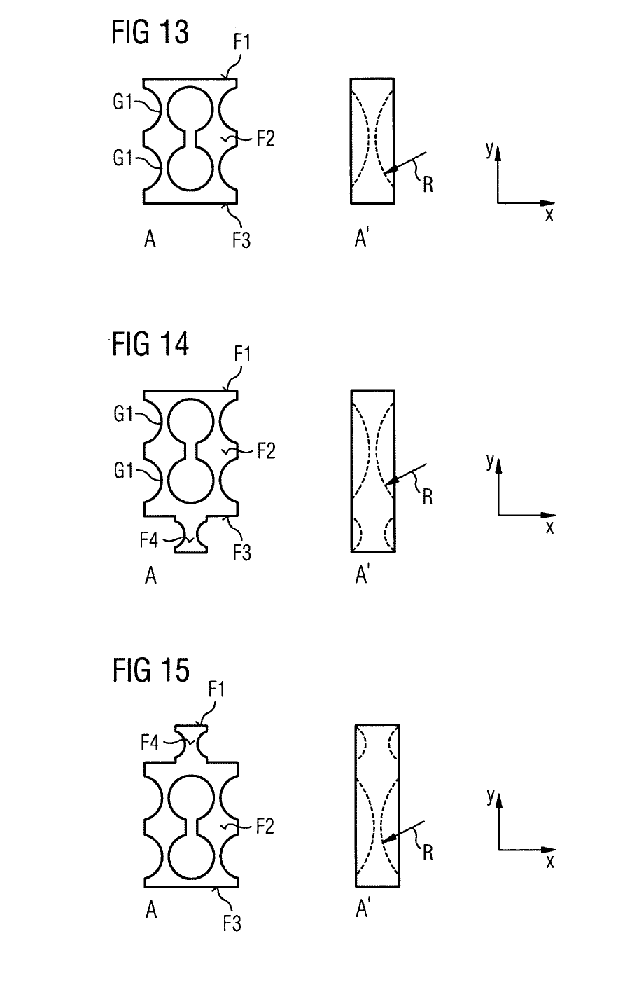

Further details of the shear-flexible structure 60 emerge from the schematics shown in FIGS. 9 to 15. FIG. 9 A shows a simplified schematic representation of the shear-flexible structure 60. This comprises two bars S1 and S2 arranged parallel to each other. These are preferably arranged parallel to the effective direction α, β of the connected bending transducer 10. The bars S1, S2 are connected via links G1, G2 to horizontally running linkage surfaces for bending transducer 10 and drive ring 20. If a deflection of the bending transducer 10 is transmitted parallel to the bars S1, S2, the shear-flexible structure 60 remains inherently stable owing to the rigidity of the bars S1, S2 and transmits the pressure and tension generated by the bending transducer 10 virtually without losses. If a shearing force F_{X}>0 (cf. FIG. 9 C) acts, due, for example, to a deflection of the bending transducer 10 arranged offset by 90°, a rotation of the bars S1, S2 takes place in relation to the horizontal linkage surfaces in the links G1, G2.

To sum up, the shear-flexible structure 60 therefore possesses the following characteristics. It is mechanically rigid in the effective direction α of the directly coupled bending transducer 10 and mechanically soft in the effective direction β of the further, not directly coupled bending transducer 10. Moreover, the shear-flexible structure 60 is also easy to manufacture. A manufacturing alternative relates to producing the drive ring 20 as a single piece with shear-flexible structure 60 and a plug-in connection to the bending transducer 10. According to one embodiment the manufacturing alternative can be implemented with the aid of an injection molding technique out of polyethylene, injection molding plastic, POM, or from other suitable materials.

Possible embodiments of the shear-flexible structure 60 are shown in FIGS. 10 to 15. As already described above, the illustrated embodiments of the shear-flexible structure 60 are also characterized by a different mechanical rigidity in the directions X and Y. On this basis a force can be transmitted by way of the great mechanical rigidity in the Y direction from the end face F1 onto the end face F3. A torque is also transmitted between the end faces F1 and F3. Only forces in the X direction are not transmitted. As shown in the embodiments of FIG. 8, the bending transducers 10 are coupled to the end face F1 and the drive ring 20 to the end face F3.

In FIGS. 10 to 15, the front views of different embodiments of the shear-flexible structure 60 are identified by A and their side views by A′. As a particular feature, a waisting of the shear-flexible structure 60 with a waisting radius R is shown in the side views of FIGS. 10 to 15. This illustration also covers the extreme case of waisting in which R approaches infinity and consequently there is longer any waist present. The waisting increases as the waisting radii R get smaller. The ratio of the rigidity in the X direction to the rigidity in the Y direction can be set by the parameter R. As the radius R becomes smaller, the rigidity in the X direction decreases, while the rigidity in the Y direction changes only slightly. The symmetries shown in FIGS. 10 to 15 are advantageous for the manufacture and function of the shear-flexible structure 60, although it must be the that they are not mandatory.

In the embodiment of the shear-flexible structure 60 according to FIG. 14, a pivot joint F4 is coupled to the shear-flexible structure 60 on the side of the drive ring 20 or, according to the embodiment of FIG. 15, on the side of the bending transducer 10. It is equally preferred to provide a pivot joint on both sides of the shear-flexible structure 60. With the aid of the pivot joint F4 a force is introduced into the shear-flexible structure 60 at a point or in a line. On the side of the coupled bending transducer 10 this means according to FIG. 15 that the force at the end of the bending transducer 10 is reduced and as a result the full active length of the bending transducer 10 can be used. It is also advantageous in the two embodiments shown in FIGS. 14 and 15 that a torque decoupling can be realized between the connected bending transducer 10 and the drive ring 20.

The layout shown in FIG. 8 represents a preferred embodiment of the actuating drive 1. The two piezoelectric bending transducers 10 are arranged inside the schematically represented housing 70. They have the respective effective direction α, β such that deflections and forces of the bending transducers 10 can be transmitted via the shear-flexible structure 60 onto the drive ring 20. The bending transducers 10 are arranged in space in such a way that the effective directions α, β intersect in the center of the drive ring 20 preferably at an angle of 90°. The piezoelectric bending transducers 10 are in each case fixedly mounted at one end on the housing 70 by the mounts 12. At the other end of the bending transducers 10 the shear-flexible structure already cited above is in each case fixedly connected to the bending transducer 10 and the drive ring 20 via the boundary surfaces 62 and 64. This connection is produced by welding, soldering, adhesive bonding, plugging-in or a similar type of fixing.

The shear-flexible structure 60 behaves mechanically rigidly in the effective direction of the associated bending transducer 10 and mechanically softly in the effective direction of further bending transducers coupled to the drive ring 20. In addition, a load torque transmitted from the shaft 30 onto the drive ring 20 is transferred to the bending transducers 10 by the shear-flexible structure 60 and finally absorbed by the housing 70. The shaft 30 is rotatably mounted on the housing 70. The shaft 30 is guided through the inner opening 28 of the drive ring 20 in such a way that it can roll in contact with the inner surface of the drive ring 20. The force is transmitted from the drive ring 20 onto the shaft 30 preferably in a friction-locked or positive-locking manner. According to one embodiment a positive-locking transmission of force is implemented by a gear teeth system, preferably a cycloidal gearing, on the drive ring 20 and the shaft 30.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-7. (canceled)

8. An electromechanical actuating drive, comprising:
at least two electromechanical drive elements each having an effective direction of deflection that is not parallel to the effective direction of deflection of the other drive element;
a shaft rotatably mounted in a drive ring in such a way that the drive ring is stimulated by deflection of the electromechanical drive elements in their respective effective directions, the electromechanical drive elements stimulating the drive ring to cause a displacement movement of the drive ring, which is directly transmitted to the shaft such that the shaft rolls in contact with the drive ring and thereby rotates; and
a slip coupling or a shear-flexible structure to link each of the electromechanical drive elements to the drive ring such that a mutual obstruction of the drive elements during the displacement movement is minimized.

9. The electromechanical actuating drive as claimed in claim 8, wherein the electromechanical drive elements are piezoelectric bending transducers.

10. The electromechanical actuating drive as claimed in claim 8, wherein
each drive element has first and second ends,
the first ends are fixedly secured to the drive ring, and
the second ends are movably connected to a housing by way of the slip coupling.
the second ends are movably connected to a housing by way of the shear-flexible structure.

12. The electromechanical actuating drive as claimed in claim 8, wherein
each drive element has first and second ends,
the first ends are fixedly secured to a housing, and
the second ends are movably connected with the drive ring by way of the slip coupling.

13. The electromechanical actuating drive as claimed in claim 12, wherein
the drive ring has projections, each projection picking up the deflection of a respective drive element,
each projection and the respective drive element are aligned in relation to the effective direction of a further drive element such that sliding of the projection on the drive element is ensured.

14. The electromechanical actuating drive as claimed in claim 8, wherein
each drive element has first and second ends,
the first ends are fixedly secured to a housing, and
the second ends are movably connected with the drive ring by way of the shear-flexible structure.

15. The electromechanical actuating drive as claimed in claim 8, wherein the respective effective directions of the drive elements are oriented in a radial direction with respect to the drive ring.

16. The electromechanical actuating drive as claimed in claim 8, wherein
the drive ring has an inner opening with a center point, and
the two electromechanical drive elements are arranged such that:
the two electromechanical drive elements lie in a plane spanned by the effective directions and in two different tangential planes that are tangential to the inner opening of the drive ring such that in the case of a rotationally symmetrical arrangement of the drive elements about the center point, the two different tangential planes are offset from one another by an angle γ in the range of 180°<γ<360°, or in the case of a mirror-symmetrical arrangement of the drive elements about an imaginary diameter of the drive ring, the two different tangential planes are offset from one another by an angle γ in the range of 0°<γ<180°, or
the two electromechanical drive elements lie outside the plane spanned by the effective directions and in two different tangential planes that are tangential to the inner opening of the drive ring, or
a first electromechanical drive element lies in the plane spanned by the effective directions, a second electromechanical drive element lies outside the plane spanned by the effective directions, and the first and second drive elements lie in two different tangential planes that are tangential to the inner opening of the drive ring.

17. The electromechanical actuating drive according to claim 8, wherein
the drive ring has an inner opening,
the two electromechanical drive elements lie in a plane spanned by the effective directions and lie respectively in two different tangential planes that are tangential to the inner opening of the drive ring, and
the two different tangential planes are substantially perpendicular to one another.

18. An electromechanical microstepper actuating drive, comprising:
two electromechanical piezoelectric drive elements, each having a longitudinal axis and an effective direction of deflection that is not parallel to the effective direction of deflection of the other drive element;
a shaft arranged in a drive ring in such a way that the drive ring is stimulated by deflection of the drive elements in their respective effective directions, the drive elements stimulating the drive ring to cause a displacement movement of the drive ring, which is directly transmitted to the shaft, wherein
each drive element has first and second ends, the first end being fixedly connected to the drive ring and the second end being fixedly connected to a housing,
the drive ring has an inner opening with a center point, and
the two drive elements are arranged such that:
the two drive elements lie in a plane spanned by the effective directions and in two different tangential planes that are tangential to the inner opening of the drive ring such that in the case of a rotationally symmetrical arrangement of the drive elements about the center point, the two different tangential planes are offset from one another by an angle γ in the range of 180°<γ<360°, or in the case of a mirror-symmetrical arrangement of the drive elements about an imaginary diameter of the drive ring, the two different tangential planes are offset from one another by an angle γ in the range of 0°<γ<180°, or
the two drive elements lie outside the plane spanned by the effective directions and in two different tangential planes that are tangential to the inner opening of the drive ring, or
a first drive element lies in the plane spanned by the effective directions, a second drive element lies outside the plane spanned by the effective directions, and the first and second drive elements lie in two different tangential planes that are tangential to the inner opening of the drive ring.
